(19) United States
(12) Patent Application Publication
(10) Pub. No.: US 2026/0352198 A1
(43) Pub. Date: Nov. 5, 2026

(54) JUNCTION FIELD EFFECT TRANSISTOR CASCODE CIRCUIT AND CORRESPONDING CONTROL CIRCUIT

(71) Applicant: Infineon Technologies Austria AG, Villach (AT)

(72) Inventors: Leo AICHRIEDLER, Puch (AT); Helena Theresa GRABNER, Pörtschach am Wörther See (AT)

(21) Appl. No.: 19/629,567

(22) Filed: Mar. 26, 2026

(30) Foreign Application Priority Data
May 2, 2025 (DE) 102025116903.9
Mar. 4, 2026 (DE) 102026108961.5

(51) Int. Cl. H03K 17/041; H03F 3/16; H03K 17/13

(52) U.S. Cl. CPC H03K 17/04106; H03F 3/165; H03K 17/133

(57) ABSTRACT

A junction field effect transistor (JFET) cascode circuit includes a gate driver configured to be supplied according to a unipolar supply scheme, the gate driver configured to output a gate drive signal from a gate drive terminal; a JFET having a JFET gate terminal configured to control a conduction of current through the JFET according to a JFET gate potential; a voltage-controlled transistor coupled to the JFET in a cascode configuration, the voltage-controlled transistor including a transistor gate terminal coupled to the gate drive terminal and configured to control a conduction of current through the voltage-controlled transistor; and a voltage-limiting circuit coupled to the gate drive terminal and the JFET gate terminal, with a voltage-limiting element configured to regulate the JFET gate potential based on the gate drive signal such that, during an on-condition of the JFET, the JFET gate potential is limited to a controlled overdrive value.

### CROSS-REFERENCE TO RELATED APPLICATION

This application claims priority to Germany Patent Application No. 102026108961.5, filed Mar. 4, 2026, and Germany Patent Application No. 102025116903.9, filed May 2, 2025, the contents of which are incorporated herein by reference in their entireties.

### BACKGROUND

Many functions of modern devices in automotive, consumer, and industrial applications, such as driving an electric motor or an electric machine, rely on power semiconductor devices. For example, insulated gate bipolar transistors (IGBTs), metal oxide semiconductor field effect transistors (MOSFETs), and diodes, to name a few, have been used for various applications including, but not limited to, switches in power supplies, power converters, and power distribution.

Solid-state switching refers to the use of electronic components (like transistors, thyristors, or solid-state relays) instead of mechanical switches or contactors to control the flow of electrical power. Unlike traditional switches, which physically move parts to make or break a circuit, solid-state switches use semiconductor materials to do this with no moving parts.

In power distribution systems, solid-state switching often needs to block current flow in both directions (positive and negative voltages) and to conduct current in both directions (positive and negative current flow). To achieve this, two semiconductor switches are typically connected source-to-source (sometimes called a back-to-back configuration). This source-to-source configuration is a key difference from a typical power converter topology (e.g., inverter or rectifier), where the goal is usually unidirectional conduction or controlled energy transfer rather than pure bidirectional interruption.

A transistor typically comprises a semiconductor structure configured to conduct a load current along a load current path between two load terminal structures of the transistor. Further, the load current may be controlled by a control electrode, sometimes referred to as a gate electrode, of the transistor. For example, upon receiving a corresponding control signal from, for example, a gate driver, the control electrode may set its transistor in one of a conducting state or a blocking state. Accordingly, the semiconductor structure behaves like a switch with on and off states (e.g., conducting and blocking states, respectively). A load current may be controlled by driving the two complementary transistors. The amplitude of the control signal received from the gate driver for each transistor may be varied to drive the two complementary transistors between switching states. For example, a gate-source voltage VGS of a MOSFET is typically driven down to approximately zero to turn off the MOSFET and is typically driven to a maximum value to fully turn on the MOSFET. For this reason, the gate-source voltage VGS may be referred to as a control voltage.

### SUMMARY

In some implementations, a junction field effect transistor (JFET) cascode circuit includes a gate driver configured to be supplied according to a unipolar supply scheme, the gate driver configured to output a gate drive signal from a gate drive terminal of the gate driver; a JFET having a JFET gate terminal configured to control a conduction of current through the JFET according to a JFET gate potential that is based on the gate drive signal; a voltage-controlled transistor coupled to the JFET in a cascode configuration, the voltage-controlled transistor including a transistor gate terminal coupled to the gate drive terminal and configured to control a conduction of current through the voltage-controlled transistor based on the gate drive signal; and a voltage-limiting circuit coupled to the gate drive terminal and the JFET gate terminal, the voltage-limiting circuit comprising a voltage-limiting element configured to regulate the JFET gate potential based on the gate drive signal such that, during a steady-state on-condition of the JFET, a maximum of the JFET gate potential is limited to a controlled overdrive value, wherein the voltage-limiting element is an active device.

A junction field effect transistor (JFET) cascode control circuit is provided. The JFET cascode control circuit is configured to control a JFET cascode circuit that comprises a voltage-controlled transistor that is coupled to a JFET in a cascode configuration. In some implementations, the JFET cascode control circuit comprises: a gate driver configured to be supplied according to a unipolar supply scheme, the gate driver configured to receive a control signal and to, based on the control signal, output a gate drive signal from a gate drive terminal configured to be coupled to a gate terminal of the voltage-controlled transistor, and a voltage-limiting circuit coupled to the gate drive terminal and comprising an overdrive terminal configured to be coupled to a JFET gate terminal of the JFET, the voltage-limiting circuit comprising a voltage-limiting element configured to output a regulated signal at the overdrive terminal based on the gate drive signal such that, during a steady-state on-condition of the JFET, a maximum of a JFET gate potential is limited to a controlled overdrive value, wherein the voltage-limiting element is an active device.

### BRIEF DESCRIPTION OF THE DRAWINGS

Implementations are described herein making reference to the appended drawings.

FIG. 1 shows a graph of drain-to-source on resistance (RDSon) vs. VGS of an n-channel high-voltage (HV)-JFET.

FIG. 2 shows an assembly of a power switch and a clamping element.

FIG. 3 is a schematic block diagram illustrating a JFET cascode circuit according to one or more implementations.

FIG. 4 is a schematic block diagram illustrating a JFET cascode circuit according to one or more implementations.

FIG. 5 is a schematic block diagram illustrating a JFET cascode circuit according to one or more implementations.

FIG. 6 is a schematic block diagram illustrating a JFET cascode circuit according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A transistor can be referred to as a power switch, a power semiconductor, a logic switch, or a transistor switch that may be used to drive a current, such as a load current. In particular, a power transistor is a power semiconductor device that may be used to drive a load current. The power transistor includes a first load terminal (e.g., a source or an emitter) and a second load terminal (e.g., a drain or a collector). Additionally, a load current path of the power transistor may be controlled by a control electrode, sometimes referred to as a gate, connected to a control terminal of the power transistor. A load current path of the power transistor is a gate-controlled conductive channel whose conductivity may be controlled by a control voltage applied to the control electrode of the power transistor. For example, the power transistor can be turned on or off by activating and deactivating its control electrode. For example, applying a positive voltage across a gate and a source of a MOSFET will keep the MOSFET in its “on” state, while applying a voltage of approximately zero or slightly negative across the gate and the source of the MOSFET will cause the MOSFET to turn “off.” As used herein, “on-state,” “on-condition,” “steady-state on-condition,” “current-conduction state,” “conduction mode,” and the like may be used interchangeably to refer to an on-state of a transistor. Additionally, “off-state,” “off-condition,” “current-blocking state,” “blocking mode,” and the like may be used interchangeably to refer to an off-state of a transistor.

There is a turn-on process and a turn-off process for switching a transistor on and off. During the turn-on process of an n-channel transistor, a gate driver may be used to provide (source) a gate current (e.g., an ON current) to a gate of the n-channel transistor in order to charge a gate voltage to a sufficient voltage to turn on the n-channel transistor. In contrast, during the turn-off process of the n-channel transistor, the gate driver is used to draw (sink) a gate current (e.g., an OFF current) from the gate of the n-channel transistor in order to discharge the gate voltage sufficiently to turn off the n-channel transistor. A voltage pulse may be output from the gate driver as a control signal according to a pulse-width modulation (PWM) scheme. Thus, the control signal may be switched between an ON voltage level and an OFF voltage level during a PWM cycle for controlling the n-channel transistor. This in turn charges and discharges gate capacitance to correspondingly modulate the gate voltage to turn on and off the n-channel transistor, respectively.

The opposite is true for a p-channel transistor. The gate driver may be used to draw (sink) a gate current (e.g., an ON current) from a gate of the p-channel transistor in order to discharge the gate voltage to a sufficient voltage to turn on the p-channel transistor. In contrast, during the turn-off process of the p-channel transistor, the gate driver is used to provide (source) a gate current (e.g., an OFF current) to the gate of the p-channel transistor in order to charge the gate voltage of the p-channel transistor sufficiently to turn off the p-channel transistor. A control signal applied to the gate of the p-channel transistor may be switched between an ON voltage level and an OFF voltage level during a PWM cycle for controlling the p-channel transistor. This in turn charges and discharges the gate voltage to turn on and off the p-channel transistor, respectively.

For both n-channel and p-channel transistors, the n-channel and p-channel transistors are off when the gate-source voltage VGS is approximately a zero value or below a threshold voltage and the n-channel and p-channel transistors are on when the gate-source voltage VGS is equal to or greater than the threshold voltage.

Another type of transistor is a junction field effect transistor (JFET). An n-channel JFET as a standalone element is a normally-on device. In order to turn-off the n-channel JFET, a negative voltage between the gate and the source contact of the n-channel JFET has to be applied (e.g., a negative VGS, where the source has a higher potential than the gate). In some applications, a normally-off behavior of the power stage is required (e.g., a connection between drain and source is in a high-impedance state while no active control signal is applied at the gate). In other applications, the introduction of negative control voltages, which would be required to put an n-channel JFET into a high-impedance state (off-state) is not practical or desired. In both cases, a JFET can be applied in series-connection with a normally-off device, such as a standard enhancement-type MOSFET, to meet design requirements. A circuit topology in which a JFET is connected in series with a normally-off device is known as a JFET cascode. However, certain characteristics of the JFET cascode must be considered in order to optimize performance of the JFET cascode.

In solid state power distribution applications, a total path resistance (e.g., drain-to-source on resistance (RDSon)) of a power stage is important. In this case, a minimal possible RDSon of a JFET may be achieved by a gate control circuit. For example, by controlling a gate-to-source voltage of the JFET during an on-state, the RDSon of the JFET may be controlled.

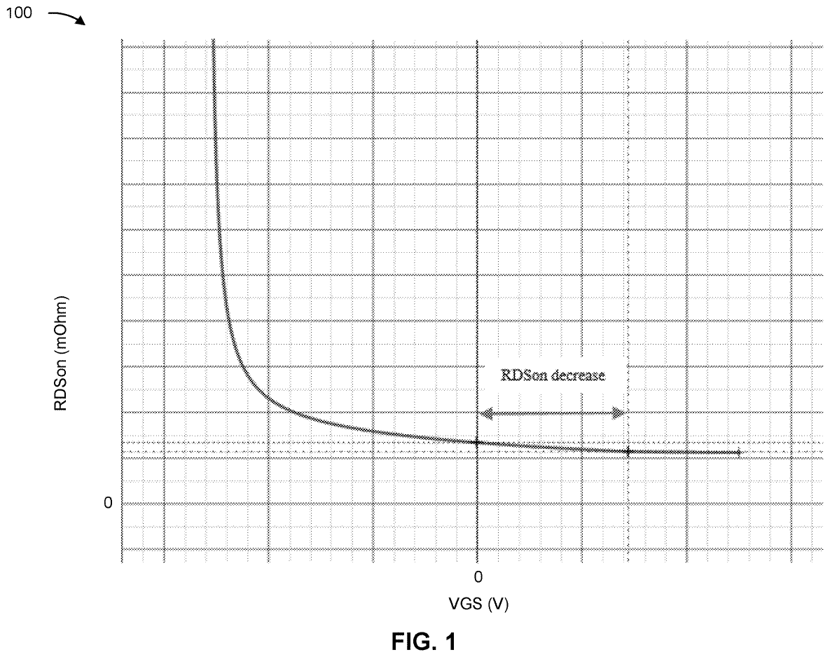

FIG. 1 shows a graph 100 of RDSon vs. VGS of an n-channel high-voltage (HV)-JFET. Some n-channel power JFETs exhibit a pronounced gate-source voltage VGS dependency of the RDSon value around VGS=0V. The application of a positive VGS further reduces a channel RDSon relative to an RDSon value present at VGS=0V. In the example illustrated in the graph 100, a 17% decrease in the RDSon may be realized by applying a positive VGS compared to the RDSon at which VGS=0V. Thus, a positive VGS may be referred to as an overdrive voltage, an overdrive gate voltage, an overdrive VGS, or an overdrive value. In other words, an overdrive voltage is a positive voltage between the gate and the source of the JFET at which RDSon is further reduced compared to VGS being equal to 0V. Due to the structure of an n-channel JFET, a maximum applicable gate voltage is limited by the JFET's intrinsic gate-to-source pn junction and gate-to-drain pn junction.

For example, once the VGS or a gate-drain voltage VGD exceed a certain voltage, such as a knee voltage, of the respective intrinsic pn junction, the intrinsic gate-to-source pn junction and gate-to-drain pn junction start to conduct high levels of gate current. The knee voltage (also called the threshold voltage) of an intrinsic pn junction is the minimum forward voltage at which the pn junction starts to conduct significantly. For example, for a silicon pn junction, the knee voltage is typically between 0.6 V and 0.7 V, and for a silicon carbide (SiC) pn junction, the knee voltage is typically between about 2.5V and 3V (note that the knee voltage of a specific intrinsic pn junction may depend on device characteristics, such as doping levels, and on temperature, for example). Conducting high levels of gate current by the intrinsic gate-to-source pn junction and gate-to-drain pn junction is not desired, as the currents through these intrinsic pn junction structures increases the power dissipation in the JFET and loads a gate driver's power supply. Furthermore, a saturation effect of d(RDSon)/d(VGS) is seen once a VGS voltage level exceeds the knee voltage of the gate-to-source pn junction and the gate-to-drain pn junction. Therefore, it may be preferred, during a steady-state on condition of the JFET (e.g., while the JFET is in an on-state) to drive the VGS level of the JFET (e.g., the overdrive voltage) close to the knee voltage level of the intrinsic pn junctions to achieve a minimum RDSon while keeping a steady-state gate current at a low level.

Transistor chip sizes applied in some applications (e.g., solid-state power distribution) can be large to achieve a desired low RDSon (e.g., <1 mOhm at VBDss ratings of 1200V, where VBDss refers to a drain-source breakdown voltage). Hence, a total gate charge (mainly a gate-drain charge (Qgd)) of JFET devices can be very high, easily exceeding 1000 nanocoulombs (nC). In order to achieve a reasonable fast switching behavior of a JFET device (dV/dt>1 kV/μs), high transient gate currents are required, which may exceed levels of 10 A. On top, high transient current capability of a gate drive circuit has to be enabled to maintain safe control of the power device during voltage transients applied across a JFET's drain-source contacts (e.g., during switching transients of an external airgap device). Therefore, it may be essential to implement a very low-impedance drive circuit for the JFET gate.

While, due to the large transistor size, the transient gate drive currents can be substantial, an average gate drive current consumption in applications of solid-state power distribution applications can be very low since the JFET operates at low switching frequencies (e.g., operating frequencies are <<1 Hz). Therefore, it is important to reduce leakage currents that are continuously fed into the JFET gate to a minimum value in order to reduce the effort of the power supply scheme for the gate drive circuit.

Shutdown current levels (current densities) applied in solid state power distribution applications can be very high, close to the specified absolute maximum pulse current levels of the power devices. Furthermore, the energy stored in the residual line/load inductance of an external circuit is absorbed by a clamping element and partly by the JFET itself.

In case of an overcurrent shutdown, a power semiconductor has to support the commutation of a shutdown current into the clamping element (e.g., a varistor (MOV), a transient voltage suppressor (TVS), a resistor-capacitor (RC)-network, or the like). As soon as the commutation is completed, the power semiconductor has to block the clamping voltage of the clamping element.

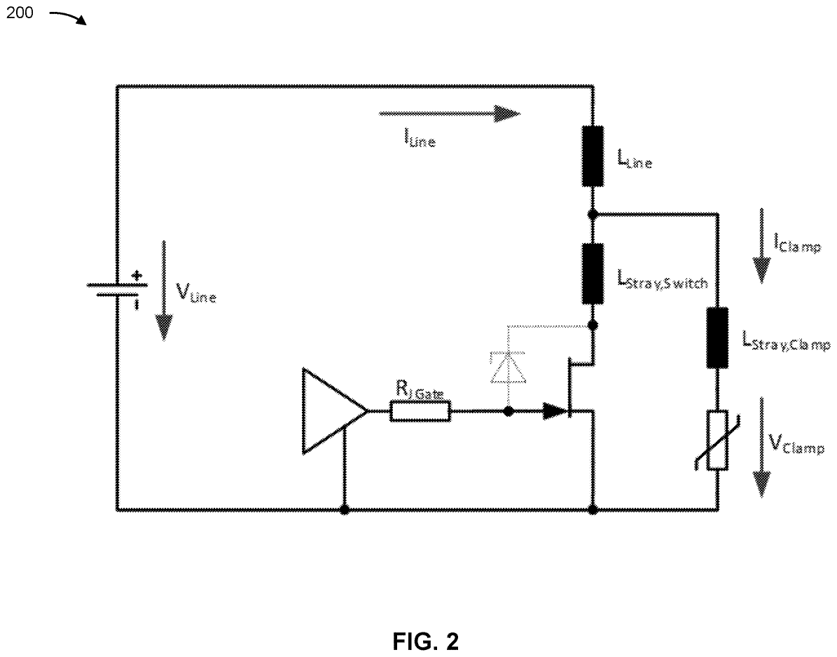

FIG. 2 shows an assembly 200 of a power switch (e.g., a JFET) and a clamping element. Both the JFET as well as the clamping element have an in-series parasitic stray inductance Lstray, Switch and LStray, Clamp, respectively. In order to achieve a successful commutation, the JFET has to provide a blocking voltage that is higher than a steady-state clamping voltage of the clamping element. The blocking voltage during commutation can be calculated by Equation 1.

V_{DS,Semiconductor}=V_{clamp}+(L_{stray,Switch}+L_{Stray,Clamp})*d(I_{Clamp})/dt (1)

While with conventional switching devices, such as MOSFETs, the switching speed of the output stage is set by control measures (e.g., increasing the gate resistance) to avoid exceeding the specified maximum VBDss of the power device, n-channel power JFET devices can be operated in an unclamped inductive switching (UIS) mode. In this way, the internal drain-gate diode is utilized to drive the JFET into linear mode and provide a controlled VDS voltage at or above a specified maximum VBDss voltage. This clamping mode must be enabled by a dedicated gate control scheme. Linear mode is achieved through the drain-gate pn junction avalanche breakdown current causing a voltage drop in the gate resistance network.

Some implementations disclosed herein are directed to a JFET cascode circuit that provides a highly efficient way of driving a discrete JFET cascode that provides a best possible RDSon at minimal circuit complexity, a required gate-drive strength, and a minimized steady-state supply current consumption. The JFET cascode circuit includes a JFET and a voltage-controlled transistor, such as a MOSFET, coupled to the JFET in a cascode configuration. For example, in the cascode configuration, a source terminal of the JFET may be coupled to a drain terminal of the voltage-controlled transistor at a cascode node. The voltage-controlled transistor may be driven to control a potential at the cascode node to place the JFET into either a current-conduction mode or a blocking mode. For example, when the voltage-controlled transistor is in the blocking mode, the cascode node may be configured to float to a higher potential than a JFET gate potential of the JFET (e.g., making VGS negative) to set the JFET into a blocking mode. Conversely, when the voltage-controlled transistor is in the current-conduction mode, a potential at the cascode node may be pulled down by the voltage-controlled transistor such that VGS is sufficient to set the JFET into a current-conduction mode. Thus, an on/off state of the JFET is indirectly controlled by controlling the on/off state of the voltage-controlled transistor, with the JFET being on based on the voltage-controlled transistor being on, and the JFET being off based on the voltage-controlled transistor being off. In the case where an overdrive signal (e.g., an overdrive potential) is applied to the gate of the JFET, the VGS of the JFET will be positive when the voltage-controlled transistor is in the current-conduction mode, thereby achieving an overdrive VGS to lower the RDSon of the JFET.

In some implementations, a JFET gate drive voltage is derived from an output voltage of a gate driver by a voltage limiter. The voltage limiter includes a voltage limit element that is an active device. An example active device is a transistor or a thyristor, whereas an example passive device is a resistor or a diode. The voltage provided to the JFET gate by the voltage limit element is limited or otherwise regulated by the voltage limiter to a level below a knee voltage of an intrinsic GS pn junction of the JFET. Due to the control of the JFET gate drive voltage, an applied VGS overdrive voltage can be set such that a reduced or a minimum RDSon can be achieved at the JFET (e.g., to a predefined reduced RDSon value), while a forward current into the intrinsic GS pn junction of the JFET is limited to a predefined current value. A current limiting element RJGATE placed between an output of the voltage limiter and the JFET gate is not required to limit the current fed into the JFET gate in a steady-state on-condition, but can be provided and sized to optimize the switching performance of the JFET, and to maintain stable operation in case of external distortions.

The gate driver includes a buffer configured to generate gate drive signal. The buffer may include a pair of complementary FETs used to generate the gate drive signal. For example, one FET (e.g., a source FET) may be connected to a positive supply potential and, when enabled, pulls the gate drive signal up toward the positive supply potential (e.g., a high level). The other FET (e.g., a sink FET) may be connected to a reference potential (e.g., a ground potential) and, when enabled, pulls the gate drive signal down toward the reference potential (e.g., a low level). When enabled, the source FET may generate an on current Io+ (e.g., a source current) to charge a gate of a transistor for turning on the transistor. When enabled, the sink FET may generate an off current Io− (e.g., a sink current) to discharge the gate of a transistor for turning off the transistor.

Thus, the gate driver is supplied according to a unipolar supply scheme that uses only one power rail (e.g., +12V) and a single ground/reference (e.g., 0V). All voltages in the system are positive (or zero) relative to the ground of the unipolar supply scheme. In other words, all voltage potentials in the circuit swing in only one polarity (e.g., positive) with respect to ground. As a result, the JFET cascode circuit is simplified relative to gate driver circuits that use a multiple supply scheme that has two or more positive supplies and/or two or more reference supplies, one of which may be negative.

When the JFET cascode circuit is turned off by the gate driver, the JFET gate may be pulled to a low level of the gate driver. Due to a blocking channel of the voltage-controlled transistor, a source potential of the JFET floats high causing a negative VGS voltage required to transition the JFET into blocking mode.

A steady-state drive current of the JFET cascode circuit arrangement is minimized to a leakage current of a gate of the voltage-controlled transistor and the JFET gate. Since a switching frequency of typical solid state power distribution applications is very low, the JFET cascode circuit allows coreless transformers to be used as a supply element, which may be important for reducing the size and cost of solid-state circuit breaker (SSCB) implementations.

Moreover, the JFET cascode circuit provides a very low-ohmic gate drive solution, enabling safe and stable operation of the JFET while minimizing the gate drive current requirements and still achieve a best possible RDSon in on-mode (e.g., during the steady-state on-condition of the JFET).

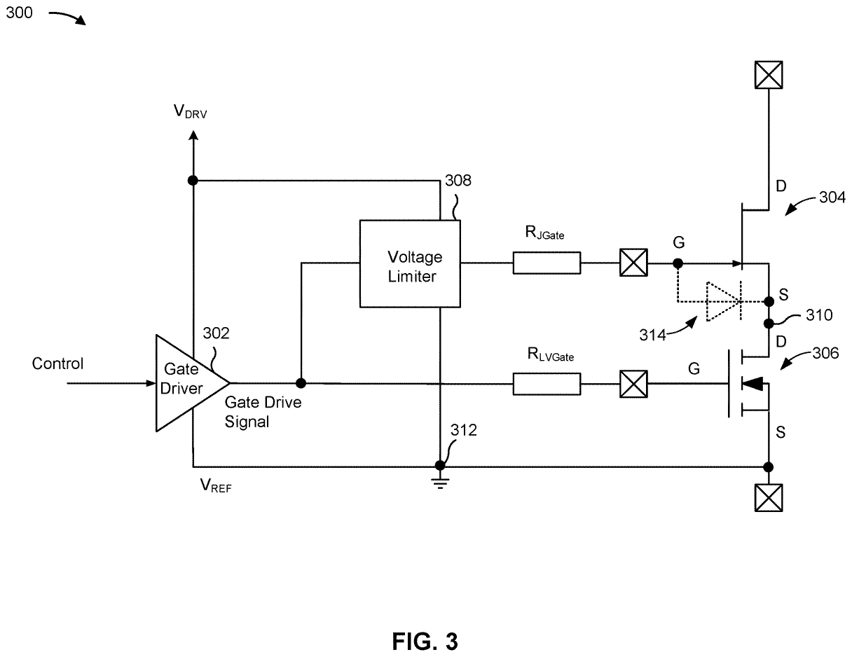

FIG. 3 is a schematic block diagram illustrating a JFET cascode circuit 300 according to one or more implementations. The JFET cascode circuit 300 may include a gate driver 302, a JFET 304, a voltage-controlled transistor 306, and a voltage-limiting circuit 308 (e.g., an overdrive voltage circuit). The JFET 304 may be an n-channel high-voltage (HV) JFET, and the voltage-controlled transistor 306 may be an n-channel low-voltage (LV) MOSFET.

The gate driver 302 is configured to be supplied according to a unipolar supply scheme. The unipolar supply scheme includes a supply potential VDRV (e.g., a single supply potential, such as +12V), sufficient for satisfying a controlled overdrive value (e.g., a controlled overdrive voltage), and a reference potential VREF (e.g., a single reference potential, such as 0V or ground). The gate driver 302 is configured to output a gate drive signal from a gate drive terminal of the gate driver 302 based on one or more control signals. For example, the gate driver 302 may receive a PWM control signal from a controller, and generate the gate drive signal based on the PWM control signal. In some implementations, two or more PWM control signals may be received by the gate driver 302 from the controller. For example, a first PWM control signal may be used to control a source FET of the gate driver 302 and a second PWM control signal may be used to control a sink FET of the gate driver 302. During an on-condition of the JFET cascode circuit 300, the gate driver 302 may set the gate drive signal to the supply potential VDRV and/or provide an on current, and during an off-condition of the JFET cascode circuit 300, the gate driver 302 may set the gate drive signal to the reference potential VREF and/or provide an off current.

The JFET 304 includes a JFET gate terminal (G) configured to control a conduction of current through the JFET according to a JFET gate potential that is based on the gate drive signal.

The voltage-controlled transistor 306 is coupled to the JFET in a cascode configuration. For example, a source terminal (S) of the JFET 304 may be coupled to a drain terminal (D) of the voltage-controlled transistor 306 at a cascode node 310 to form the cascode configuration. A source terminal (S) of the voltage-controlled transistor 306 may be coupled to a common source node 312 of the JFET cascode circuit 300, where the common source node 312 is coupled to the reference potential VREF. Thus, the source terminal (S) of the voltage-controlled transistor 306 may be grounded.

The voltage-controlled transistor 306 includes a transistor gate terminal (G) coupled to the gate drive terminal of the gate driver 302 and is configured to control a conduction of current through the voltage-controlled transistor 306 based on the gate drive signal.

The voltage-limiting circuit 308 is coupled to the gate drive terminal and to the JFET gate terminal. The voltage-limiting circuit 308 includes at least one voltage-limiting element configured to regulate the JFET gate potential based on the gate drive signal such that, during a steady-state on-condition of the JFET 304, a maximum of the JFET gate potential is limited to a controlled overdrive value. For example, the JFET gate potential may be limited according to a controlled overdrive potential VOD provided by the voltage-limiting circuit 308. In some implementations, the JFET gate potential is set by the voltage-limiting circuit 308, during the steady-state on-condition of the JFET 304, to the controlled overdrive value. Accordingly, a controlled overdrive voltage (e.g., controlled overdrive VGS) may be established between the gate and source terminals of the JFET 304 during the steady-state on-condition of the JFET 304. A gate-to-source pn junction 314 of the JFET 304 is represented as a diode in FIG. 3. The gate-to-source pn junction 314 is an intrinsic gate-to-source pn junction formed by the gate and the source of the JFET 304. The JFET 304 also includes a gate-to-drain pn junction, intrinsically formed by the gate and the drain of the JFET 304. The voltage-limiting element is an active device. For example, the voltage-limiting element may be a transistor or an operational amplifier.

In some implementations, the voltage-limiting circuit 308 may be configured to provide the controlled overdrive value at the JFET gate as a positive value that is less than a knee voltage of the gate-to-source pn junction 314 (e.g., the controlled overdrive VGS is less than a knee voltage of the gate-to-source pn junction 314). In some implementations, the controlled overdrive value may be a voltage level at which an RDSon of the JFET 304 is minimized or set to a predefined value without the voltage level exceeding the knee voltage of the gate-to-source pn junction. In other words, the controlled overdrive value may be a positive value at which controlled overdrive VGS causes the RDSon of the JFET 304 to be minimized or to be set to a predefined value without the controlled overdrive VGS exceeding the knee voltage of the gate-to-source pn junction.

In some implementations, the voltage-limiting element of the voltage-limiting circuit 308 may, during the steady-state on-condition of the JFET, bias the JFET gate terminal according to the controlled overdrive value, where the controlled overdrive value is a voltage level at which the RDSon of the JFET 304 is minimized or set to a predefined value.

In some implementations, the voltage-limiting element of the voltage-limiting circuit 308 may, during the steady-state on-condition of the JFET, limit a forward current flowing into the gate-to-source pn junction 314 to a predefined value.

During operation, the gate driver 302 set the gate drive signal to the supply potential VDRV to turn on the voltage-controlled transistor 306, causing the JFET 304 to be set into a current-conduction state. Alternatively, the gate driver 302 may set the gate drive signal to the reference potential VREF to turn off the voltage-controlled transistor 306, causing the JFET 304 to be set into a blocking state. In some implementations, the voltage-limiting element of the voltage-limiting circuit 308 may to, during an off-condition of the JFET 304, set the JFET gate potential to the reference potential VREF, which may aid in turning off the JFET 304 by making the VGS of the JFET 304 more negative. For example, the cascode node 310 may be configured to, during an off-condition of the JFET 304, float to a higher potential than the JFET gate potential, to set the JFET 304 into the blocking state. For example, when the voltage-controlled transistor 306 is placed in a blocking state by the gate drive signal, the blocking state of the voltage-controlled transistor 306 may cause the cascode node 310 may float to a higher potential than the JFET gate potential, making the VGS of the JFET 304 sufficiently negative to turn off the JFET 304.

In some implementations, the voltage-limiting element is configured to receive the gate drive signal as a supply input, and limit the gate drive signal at an output of the voltage-limiting element such that the JFET gate potential is limited to the controlled overdrive value. Alternatively, in some implementations, the voltage-limiting element is configured to receive the supply potential VDRV as a supply input, and limit the supply potential VDRV at an output of the voltage-limiting element such that the JFET gate potential is limited to the controlled overdrive value.

The JFET cascode circuit 300 may also include current limiting elements (e.g., gate resistors) connected to the gates of the JFET 304 and the voltage-controlled transistor 306. For example, a first current limiting element RJGATE may be coupled to the JFET gate terminal of the JFET 304, and a second current limiting element RLVGATE may be coupled to the transistor gate terminal of the voltage-controlled transistor 306. The first current limiting element RJGATE placed between an output of the voltage-limiting circuit 308 and the JFET gate may be provided and sized to optimize a switching performance of the JFET 304, and to maintain stable operation in case of external distortions.

As indicated above, FIG. 3 is provided merely as an example. Other examples may differ from what is described with regard to FIG. 3.

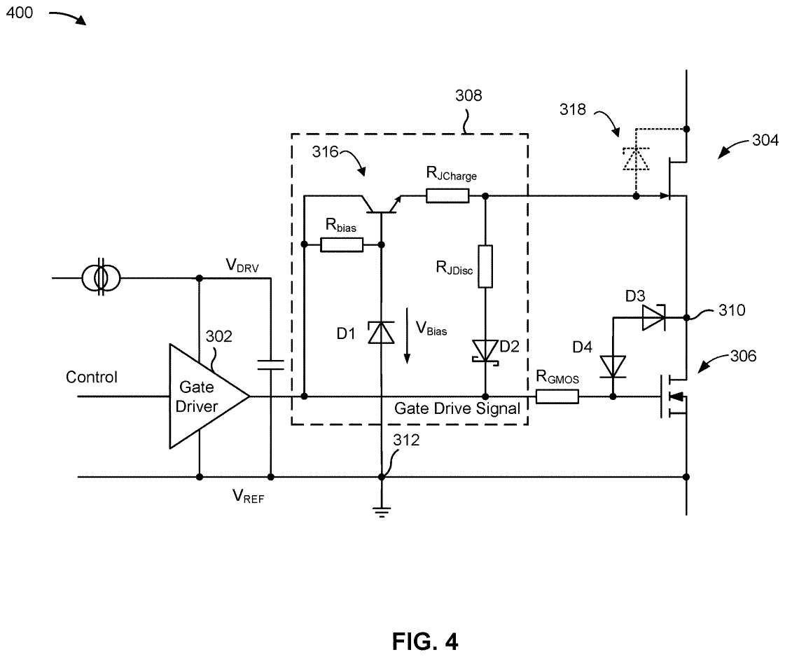

FIG. 4 is a schematic block diagram illustrating a JFET cascode circuit 400 according to one or more implementations. The JFET cascode circuit 400 may be similar to the JFET cascode circuit 300 described in connection with FIG. 3, with one example implementation of the voltage-limiting circuit 308 in more detail. Thus, the JFET cascode circuit 400 includes a gate driver 302, a JFET 304, a voltage-controlled transistor 306, and a voltage-limiting circuit 308 (e.g., an overdrive voltage circuit), as described above in connection with FIG. 3.

In the example shown in FIG. 4, a voltage-limiting element 316 of the voltage-limiting circuit 308 is shown as a transistor. In some implementations, the voltage-limiting element 316 may be an npn-transistor. The voltage-limiting element 316 may be configured to receive the gate drive signal as a supply input, and limit the gate drive signal at an output of the voltage-limiting element 316 such that the JFET gate potential is limited to the controlled overdrive value. For example, the voltage-limiting element 316 may receive the gate drive signal as a supply input at a collector terminal of the voltage-limiting element 316, and limit the gate drive signal at an emitter terminal of the voltage-limiting element 316.

When the gate driver 302 is driving a high level (e.g., VDRV), Zener diode D1 is biased via a bias resistor Rbias and sets a reference bias voltage VBias. During a turn-on event or a negative voltage transient at the JFET drain-contact, the voltage-limiting element 316 provides a very low impedance output to the JFET gate, which enables a fast turn-on of the JFET 304 from an off-state and a stable gate voltage during voltage transients. A charge resistor Rjcharge can be implemented to tune a turn-on characteristic (e.g., a negative dV/dt switching slope) of the JFET 304.

The cascode is turned off through the gate driver 302 by pulling the gate drive line to the reference potential VREF. The JFET gate potential is discharged to the gate driver output voltage via an RjDisc/D2 discharge path formed by discharge resistor RjDisc and a diode D2. At the same time, the voltage-controlled transistor 306 starts to block, causing the cascode node 310 voltage to rise. Once the VGS of the JFET 304 has decreased below a pinch-off voltage of the JFET 304, the JFET 304 is set into blocking condition and the cascode configuration is in an off-condition.

In some implementations, the JFET 304 may be used to absorb UIS energies within a high-voltage switch arrangement. The JFET cascode circuit 400 may enable a controlled UIS operation of the cascode configuration, by enabling a stable, linear mode operation. The JFET 304 may be designed in a way that a drain-to-gate breakdown voltage of the JFET 304 is lower than a drain-to-source breakdown voltage of the JFET 304. In this way, a VDS-voltage of the JFET increases until a gate-to-drain pn junction 318 of the JFET 304 reaches avalanche breakdown voltage of the gate-to-drain pn junction 318. As avalanche current provided at the JFET gate terminal causes a voltage drop across the discharge path RjDisc/D2, which leads to an increase of an effective VGS-voltage at the JFET 304. At the same time, a VDS voltage at the voltage-controlled transistor 306 is controlled and limited to a fixed level determined by a diode feedback network D3/D4, formed by a pair of back-to-back-coupled diodes D3 and D4, where diode D3 may be a Zener diode that provides a reference voltage and diode D4 may be a junction diode. In this way, the JFET 304 and the voltage-controlled transistor 306 both operate in a linear mode at defined VDS ratings until an unclamped current has decayed. Once the VDS voltage collapses, the JFET gate is discharged to the reference potential VREF, and the cascode node 310 settles to a required voltage to pinch-off the JFET 304.

The voltage-limiting circuit 308 may include a Zener diode D1 having a cathode coupled to a reference node (e.g., the common source node 312) of the JFET cascode circuit 400, and an anode coupled to a control terminal (e.g., a base terminal) of the voltage-limiting element 316. Thus, the cathode of the Zener diode D1 is coupled to the reference potential VREF (e.g., a ground potential). A voltage reference element may be coupled between the control terminal of the voltage-limiting element 316 and the reference node. The voltage reference element may be configured to be biased by the gate drive signal such that a signal provided by the voltage reference element depends on a state of the gate drive signal. For example, the voltage reference element may be the Zener diode D1 having a first cathode coupled to a reference node of the JFET cascode circuit, and a first anode coupled to a control terminal of the voltage-limiting element. The bias resistor Rbias coupled to the gate drive terminal on one end and to the anode of the Zener diode D1 on another end. The gate driver 302 may drive the gate drive signal between a high level and a low level. Accordingly, the Zener diode D1 may, based on the gate drive signal being at the high level, conduct current in a reverse-conduction mode and set a voltage at the control terminal of the voltage-limiting element 316 to a reverse-bias reference voltage of the Zener diode D1 (e.g., to a Zener breakdown voltage of the Zener diode D1). The gate driver 302 is coupled to the common source node 312, and the low level corresponds to the reference potential VREF at the common source node 312.

Additionally, the voltage-limiting circuit 308 may include a diode D2, such as a Schottky diode, having a cathode coupled to the gate drive terminal, and an anode coupled to the output of the voltage-limiting element 316 and to the JFET gate terminal. The diode D2 may, based on the gate drive signal being at the low level, discharge the JFET gate terminal to the low level (e.g., to the reference potential VREF).

A gate resistor RGMOS may be coupled between the gate drive terminal and the transistor gate terminal of the voltage-controlled transistor 306 for providing the gate drive signal to the transistor gate terminal of the voltage-controlled transistor 306. A pair of back-to-back-coupled diodes D3 and D4 may be respectively coupled to the drain terminal of the voltage-controlled transistor 306 and to the transistor gate terminal of the voltage-controlled transistor 306, for reasons described above. The pair of back-to-back-coupled diodes D3 and D4 may be arranged between the gate resistor RGMOS and the transistor gate terminal of the voltage-controlled transistor 306.

In some implementations, the discharge path may be coupled to the reference potential VREF (e.g., a ground potential) instead of to the gate drive terminal (e.g., to the gate drive signal line), and diode D2 may be replaced by an active element, such as a transistor.

As indicated above, FIG. 4 is provided merely as an example. Other examples may differ from what is described with regard to FIG. 4.

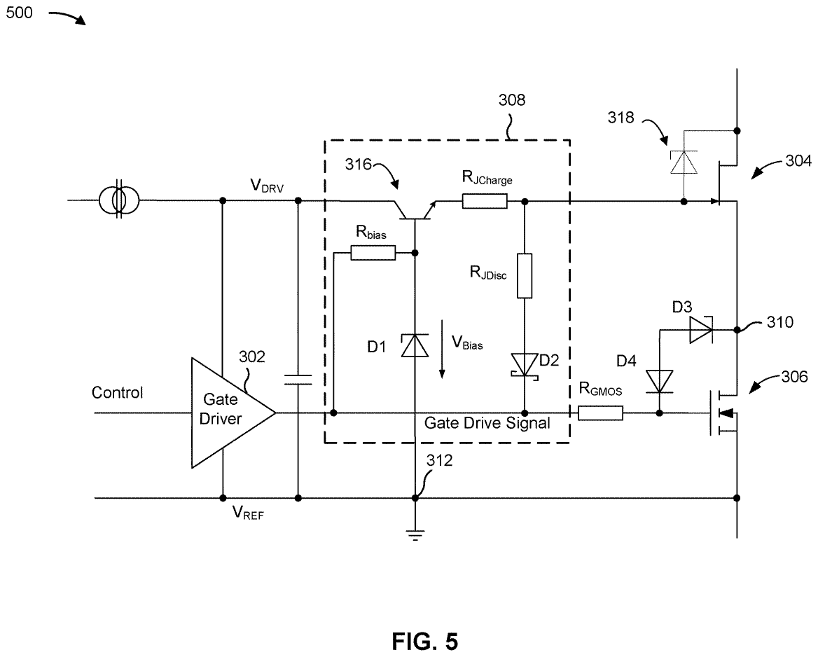

FIG. 5 is a schematic block diagram illustrating a JFET cascode circuit 500 according to one or more implementations. The JFET cascode circuit 500 may be similar to the JFET cascode circuit 300 described in connection with FIG. 3, with one example implementation of the voltage-limiting circuit 308 in more detail. Moreover, the JFET cascode circuit 500 may be similar to the JFET cascode circuit 400 described in connection with FIG. 4, with an exception that the voltage-limiting element 316 is configured to receive the supply potential VDRV as a supply input (instead of the gate drive signal, as shown in FIG. 4), and limit the supply potential VDRV at an output of the voltage-limiting element 316 such that the JFET gate potential is limited to the controlled overdrive value. Thus, a supply current for the voltage-limiting element 316 can be taken directly from a supply pin of the gate driver 302 or a positive supply rail of the gate driver 302. As a result, a gate drive strength for driving the JFET 304 may be further enhanced relative to the JFET cascode circuit 400, as an output of the gate driver 302 does not limit a total current to be supplied to the JFET gate terminal during transients, but only has to provide a base current of the voltage-limiting element 316 (e.g., an npn-transistor). In other words, by connecting the collector of the voltage-limiting element 316 to the supply pin of the gate driver 302, the gate drive signal is no longer responsible for supplying current to the collector terminal of the voltage-limiting element 316, but only has to supply current for controlling the control terminal of the voltage-limiting element 316. The voltage-limiting element 316 may be a current-controlled transistor, such as a bipolar junction transistor (BJT), or a voltage-controlled transistor.

When the gate drive signal is at a high level, the bias resistor Rbias causes a potential at the anode of the Zener diode D1 to increase, and consequently, at the control terminal of the voltage-limiting element 316 to increase. Thus, the Zener diode D1 is configured to, based on the gate drive signal being at the high level, conduct current in a reverse-conduction mode and set a voltage at the control terminal of the voltage-limiting element to the reverse-bias reference voltage of the Zener diode D1 (e.g., to a Zener breakdown voltage of the Zener diode D1). The Zener diode D1 further has a cathode coupled to a reference node of the JFET cascode circuit 500 (e.g., at the common source node 312). Thus, the cathode of the Zener diode D1 is coupled to the reference potential VREF (e.g., a ground potential).

As indicated above, FIG. 5 is provided merely as an example. Other examples may differ from what is described with regard to FIG. 5.

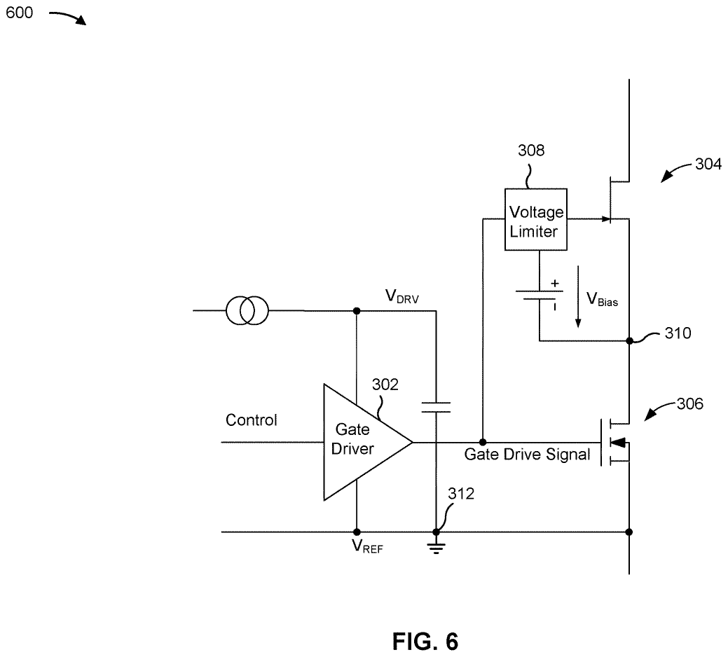

FIG. 6 is a schematic block diagram illustrating a JFET cascode circuit 600 according to one or more implementations. The JFET cascode circuit 600 may be similar to the JFET cascode circuit 400 described in connection with FIG. 4, with an exception that the reference node to which the cathode of the Zener diode D1 is coupled is the cascode node 310 (e.g., instead of being coupled to the common source node 312). In this case, a diode to block any forward current through the Zener diode D1 may be provided additionally in series to the Zener diode D1. Alternatively, The JFET cascode circuit 600 may be similar to the JFET cascode circuit 500 described in connection with FIG. 5, with an exception that the reference node to which the cathode of the Zener diode D1 is coupled is the cascode node 310 (e.g., instead of being coupled to the common source node 312). Thus, the Zener diode D1 may have a cathode coupled to a reference node (e.g., the cascode node 310) of the JFET cascode circuit 600, and an anode coupled to a control terminal of the voltage-limiting element 316. In this case, a diode to block any forward current through the Zener diode D1 may be provided additionally in series to the Zener diode D1. However, implementations other than using Zener diodes are also possible. For example, any other element suitable to provide a voltage reference other than a Zener diode may be used to connect the voltage limiting circuit 308 to the cascode node 310, thereby providing a predefined bias voltage V_Bias, as is depicted in FIG. 6.

In some examples, a high voltage drop may be produced across the voltage-controlled transistor 306, and the VGS overdrive voltage of the JFET 304 may be reduced causing an increase of the JFET's RDSon. Thus, in cases where a high voltage drop is produced across the voltage-controlled transistor 306, using the cascode node 310 as the reference node for the voltage-limiting circuit 308 may be beneficial to maintain the VGS overdrive voltage of the JFET 304 at a desired level and reduce the RDSon of the JFET 304 to a desired level without the VGS overdrive voltage exceeding the knee voltage of the of the gate-to-source pn junction of the JFET 304.

As indicated above, FIG. 6 is provided merely as an example. Other examples may differ from what is described with regard to FIG. 6.

The following provides an overview of some Aspects of the present disclosure:

Aspect 1: A JFET cascode circuit, comprising: a gate driver configured to be supplied according to a unipolar supply scheme, the gate driver configured to output a gate drive signal from a gate drive terminal of the gate driver; a JFET having a JFET gate terminal configured to control a conduction of current through the JFET according to a JFET gate potential that is based on the gate drive signal; a voltage-controlled transistor coupled to the JFET in a cascode configuration, the voltage-controlled transistor including a transistor gate terminal coupled to the gate drive terminal and configured to control a conduction of current through the voltage-controlled transistor based on the gate drive signal; and a voltage-limiting circuit coupled to the gate drive terminal and the JFET gate terminal, the voltage-limiting circuit comprising a voltage-limiting element configured to regulate the JFET gate potential based on the gate drive signal such that, during a steady-state on-condition of the JFET, a maximum of the JFET gate potential is limited to a controlled overdrive value, wherein the voltage-limiting element is an active device.

Aspect 2: The JFET cascode circuit of Aspect 1, wherein the JFET includes a gate-to-source pn junction, and wherein the controlled overdrive value is a positive value that is less than a knee voltage of the gate-to-source pn junction.

Aspect 3: The JFET cascode circuit of Aspect 2, wherein the controlled overdrive value is a voltage level at which a drain-to-source on resistance of the JFET is minimized without the voltage level exceeding the knee voltage of the gate-to-source pn junction.

Aspect 4: The JFET cascode circuit of any of Aspects 1-3, wherein the voltage-limiting element is configured to, during the steady-state on-condition of the JFET, bias the JFET gate terminal according to the controlled overdrive value, and wherein the controlled overdrive value is a voltage level at which a drain-to-source on resistance of the JFET is minimized.

Aspect 5: The JFET cascode circuit of any of Aspects 1-4, wherein the JFET includes a gate-to-source pn junction formed by a gate and a source of the JFET, and wherein the voltage-limiting element is configured to, during the steady-state on-condition of the JFET, limit a forward current flowing into the gate-to-source pn junction to a predefined value.

Aspect 6: The JFET cascode circuit of any of Aspects 1-5, wherein the unipolar supply scheme includes a supply potential, sufficient for satisfying the controlled overdrive value, and a reference potential, wherein the gate driver is configured to set the gate drive signal to the supply potential to turn on the voltage-controlled transistor, causing the JFET to be set into a current-conduction state, wherein the gate driver is configured to set the gate drive signal to the reference potential to turn off the voltage-controlled transistor, causing the JFET to be set into a blocking state, and wherein the voltage-limiting element is configured to, during an off-condition of the JFET, set the JFET gate potential to the reference potential.

Aspect 7: The JFET cascode circuit of Aspect 6, wherein a source terminal of the JFET and a drain terminal of the voltage-controlled transistor are coupled at a cascode node to form the cascode configuration, and wherein the cascode node is configured to, during an off-condition of the JFET, float to a higher potential than the JFET gate potential, to set the JFET into the blocking state.

Aspect 8: The JFET cascode circuit of any of Aspects 1-7, wherein the voltage-limiting element is configured to receive the gate drive signal as a supply input, and limit the gate drive signal at an output of the voltage-limiting element such that the JFET gate potential is limited to the controlled overdrive value.

Aspect 9: The JFET cascode circuit of Aspect 8, wherein the voltage-limiting element is a transistor, and wherein the voltage-limiting circuit further comprises: a voltage reference element coupled between the control terminal of the voltage-limiting element and the reference node, wherein the voltage reference element is configured to be biased by the gate drive signal such that a signal provided by the voltage reference element depends on a state of the gate drive signal, wherein the gate driver is configured to drive the gate drive signal between a high level and a low level, and wherein the voltage reference element is configured to, based on the gate drive signal being at the high level, conduct current in a reverse-conduction mode and set a voltage at the control terminal of the voltage-limiting element to a reverse-bias reference voltage.

Aspect 10: The JFET cascode circuit of Aspect 9, wherein the voltage reference element is a Zener diode having a first cathode coupled to a reference node of the JFET cascode circuit, and a first anode coupled to a control terminal of the voltage-limiting element, and wherein a bias resistor is coupled to the gate drive terminal and the first anode of the Zener diode.

Aspect 11: The JFET cascode circuit of Aspect 9, wherein the reference node is a common source node of the JFET cascode circuit, the common source node corresponding to a source terminal of the voltage-controlled transistor.

Aspect 12: The JFET cascode circuit of Aspect 11, wherein the gate driver is coupled to the common source node, and wherein the low level corresponds to a reference potential at the common source node.

Aspect 13: The JFET cascode circuit of Aspect 9, wherein the JFET and the voltage-controlled transistor are coupled at a cascode node, and wherein the reference node is the cascode node.

Aspect 14: The JFET cascode circuit of Aspect 9, wherein the voltage-limiting circuit further comprises: a diode having a second cathode coupled to the gate drive terminal, and a second anode coupled to the output of the voltage-limiting element and to the JFET gate terminal, wherein the diode is configured to, based on the gate drive signal being at the low level, discharge the JFET gate terminal to the low level.

Aspect 15: The JFET cascode circuit of Aspect 8, further comprising: a gate resistor coupled between the gate drive terminal and the transistor gate terminal of the voltage-controlled transistor for providing the gate drive signal to the transistor gate terminal of the voltage-controlled transistor; and a pair of back-to-back-coupled diodes coupled to a drain terminal of the voltage-controlled transistor and to the transistor gate terminal of the voltage-controlled transistor, the pair of back-to-back-coupled diodes being arranged between the gate resistor and the transistor gate terminal of the voltage-controlled transistor, wherein one diode of the pair of back-to-back-coupled diodes is a Zener diode that provides a reference voltage.

Aspect 16: The JFET cascode circuit of any of Aspects 1-15, wherein a drain-to-gate breakdown voltage of the JFET is lower than a drain-to-source breakdown voltage of the JFET.

Aspect 17: The JFET cascode circuit of any of Aspects 1-16, wherein the unipolar supply scheme includes a supply potential, sufficient for satisfying the controlled overdrive value, and a reference potential, and wherein the voltage-limiting element is configured to receive the supply potential as a supply input, and limit the supply potential at an output of the voltage-limiting element such that the JFET gate potential is limited to the controlled overdrive value.

Aspect 18: The JFET cascode circuit of Aspect 17, wherein the voltage-limiting element is a transistor, and wherein the voltage-limiting circuit further comprises: a voltage reference element coupled between the control terminal of the voltage-limiting element and the reference node, wherein the voltage reference element is configured to be biased by the gate drive signal such that a signal provided by the voltage reference element depends on a state of the gate drive signal, wherein the gate driver is configured to drive the gate drive signal between a high level and a low level, and wherein the voltage reference element is configured to, based on the gate drive signal being at the high level, conduct current in a reverse-conduction mode and set a voltage at the control terminal of the voltage-limiting element to a reverse-bias reference voltage.

Aspect 19: The JFET cascode circuit of Aspect 18, wherein the reference node is a common source node of the JFET cascode circuit, the common source node corresponding to a source terminal of the voltage-controlled transistor.

Aspect 20: The JFET cascode circuit of Aspect 19, wherein the gate driver is coupled to the common source node, and wherein the low level corresponds to a reference potential at the common source node.

Aspect 21: The JFET cascode circuit of Aspect 18, wherein the voltage-limiting circuit further comprises: a diode having a second cathode coupled to the gate drive terminal, and a second anode coupled to the output of the voltage-limiting element and to the JFET gate terminal, wherein the diode is configured to, based on the gate drive signal being at the low level, discharge the JFET gate terminal to the low level.

Aspect 22: The JFET cascode circuit of any of Aspects 1-21, wherein the voltage-limiting element is configured to, during an off-condition of the JFET, set the JFET gate potential to a low-voltage level of the unipolar supply scheme.

Aspect 23: A junction field effect transistor (JFET) cascode control circuit configured to control a JFET cascode circuit that comprises a voltage-controlled transistor that is coupled to a JFET in a cascode configuration, the JFET cascode control circuit comprising: a gate driver configured to be supplied according to a unipolar supply scheme, the gate driver configured to receive a control signal and to, based on the control signal, output a gate drive signal from a gate drive terminal configured to be coupled to a gate terminal of the voltage-controlled transistor, and a voltage-limiting circuit coupled to the gate drive terminal and comprising an overdrive terminal configured to be coupled to a JFET gate terminal of the JFET, the voltage-limiting circuit comprising a voltage-limiting element configured to output a regulated signal at the overdrive terminal based on the gate drive signal such that, during a steady-state on-condition of the JFET, a maximum of a JFET gate potential is limited to a controlled overdrive value, wherein the voltage-limiting element is an active device.

Aspect 24: The junction field effect transistor (JFET) cascode control circuit of Aspect 23, wherein the unipolar supply scheme includes a supply potential, sufficient for satisfying the controlled overdrive value, and a reference potential, wherein, when the control signal indicates a turn on of the JFET cascode circuit: the gate driver is configured to set the gate drive signal to the supply potential to turn on the voltage-controlled transistor and the voltage-limiting element is configured output the regulated signal in accordance with the controlled overdrive value, and wherein, when the control signal indicates a turn off of the JFET cascode circuit: the gate driver is configured to set the gate drive signal to the reference potential to turn off the voltage-controlled transistor and the voltage-limiting element is configured to set the overdrive terminal to the reference potential.

Aspect 25: The junction field effect transistor (JFET) cascode control circuit of Aspect 23, wherein the voltage-limiting element is configured to receive the gate drive signal as a supply input, and limit the gate drive signal at an output of the voltage-limiting element such that the regulated signal at the overdrive terminal is limited to the controlled overdrive value.

Aspect 26: The JFET cascode control circuit of Aspect 25, wherein the voltage-limiting element is a transistor, and wherein the voltage-limiting circuit further comprises: a voltage reference element coupled between the control terminal of the voltage-limiting element and the reference node, wherein the voltage reference element is configured to be biased by the gate drive signal such that a signal provided by the voltage reference element depends on a state of the gate drive signal, wherein the gate driver is configured to drive the gate drive signal between a high level and a low level, and wherein the voltage reference element is configured to, based on the gate drive signal being at the high level, conduct current in a reverse-conduction mode and set a voltage at the control terminal of the voltage-limiting element to a reverse-bias reference voltage.

Aspect 27: The JFET cascode control circuit of Aspect 26, wherein the voltage-limiting circuit further comprises: a diode having a second cathode coupled to the gate drive terminal, and a second anode coupled to the output of the voltage-limiting element and to the overdrive terminal, wherein the diode is configured to, based on the gate drive signal being at the low level, sink a current from the overdrive terminal to discharge the JFET gate terminal to the low level.

Aspect 28: The JFET cascode control circuit of Aspect 23, wherein the unipolar supply scheme includes a supply potential, sufficient for satisfying the controlled overdrive value, and a reference potential, and wherein the voltage-limiting element is configured to receive the supply potential as a supply input, and limit the supply potential at an output of the voltage-limiting element such that the regulated signal at the overdrive terminal is limited to the controlled overdrive value.

Aspect 29: The JFET cascode control circuit of Aspect 28, wherein the voltage-limiting element is a transistor, and wherein the voltage-limiting circuit further comprises: a voltage reference element coupled between the control terminal of the voltage-limiting element and the reference node, wherein the voltage reference element is configured to be biased by the gate drive signal such that a signal provided by the voltage reference element depends on a state of the gate drive signal, wherein the gate driver is configured to drive the gate drive signal between a high level and a low level, and wherein the voltage reference element is configured to, based on the gate drive signal being at the high level, conduct current in a reverse-conduction mode and set a voltage at the control terminal of the voltage-limiting element to a reverse-bias reference voltage.

Aspect 30: A system configured to perform one or more operations recited in one or more of Aspects 1-29.

Aspect 31: An apparatus comprising means for performing one or more operations recited in one or more of Aspects 1-30.

Aspect 32: A non-transitory computer-readable medium storing a set of instructions, the set of instructions comprising one or more instructions that, when executed by a device, cause the device to perform one or more operations recited in one or more of Aspects 1-29.

Aspect 33: A computer program product comprising instructions or code for executing one or more operations recited in one or more of Aspects 1-29.

The foregoing disclosure provides illustration and description, but is not intended to be exhaustive or to limit the implementations to the precise form disclosed. Modifications and variations may be made in light of the above disclosure or may be acquired from practice of the implementations.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. Systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein, refers to any of the foregoing structures or any other structure suitable for implementation of the techniques described herein. Software may be stored on a non-transitory computer-readable medium such that the non-transitory computer readable medium includes program code or a program algorithm stored thereon that, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal, further information. “Signal conditioning,” as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation, and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

1. A junction field effect transistor (JFET) cascode circuit, comprising:
a gate driver configured to be supplied according to a unipolar supply scheme, the gate driver configured to output a gate drive signal from a gate drive terminal of the gate driver;
a JFET having a JFET gate terminal configured to control a conduction of current through the JFET according to a JFET gate potential that is based on the gate drive signal;
a voltage-controlled transistor coupled to the JFET in a cascode configuration, the voltage-controlled transistor including a transistor gate terminal coupled to the gate drive terminal and configured to control a conduction of current through the voltage-controlled transistor based on the gate drive signal; and
a voltage-limiting circuit coupled to the gate drive terminal and the JFET gate terminal, the voltage-limiting circuit comprising a voltage-limiting element configured to regulate the JFET gate potential based on the gate drive signal such that, during a steady-state on-condition of the JFET, a maximum of the JFET gate potential is limited to a controlled overdrive value,
wherein the voltage-limiting element is an active device.

2. The JFET cascode circuit of claim 1, wherein the JFET includes a gate-to-source pn junction, and
wherein the controlled overdrive value is a positive value that is less than a knee voltage of the gate-to-source pn junction.

3. The JFET cascode circuit of claim 2, wherein the controlled overdrive value is a voltage level at which a drain-to-source on resistance of the JFET is minimized without the voltage level exceeding the knee voltage of the gate-to-source pn junction.

4. The JFET cascode circuit of claim 1, wherein the voltage-limiting element is configured to, during the steady-state on-condition of the JFET, bias the JFET gate terminal according to the controlled overdrive value, and
wherein the controlled overdrive value is a voltage level at which a drain-to-source on resistance of the JFET is minimized.

5. The JFET cascode circuit of claim 1, wherein the JFET includes a gate-to-source pn junction formed by a gate and a source of the JFET, and
wherein the voltage-limiting element is configured to, during the steady-state on-condition of the JFET, limit a forward current flowing into the gate-to-source pn junction to a predefined value.

6. The JFET cascode circuit of claim 1, wherein the unipolar supply scheme includes a supply potential, sufficient for satisfying the controlled overdrive value, and a reference potential,
wherein the gate driver is configured to set the gate drive signal to the supply potential to turn on the voltage-controlled transistor, causing the JFET to be set into a current-conduction state,
wherein the gate driver is configured to set the gate drive signal to the reference potential to turn off the voltage-controlled transistor, causing the JFET to be set into a blocking state, and
wherein the voltage-limiting element is configured to, during an off-condition of the JFET, set the JFET gate potential to the reference potential.

7. The JFET cascode circuit of claim 1, wherein the voltage-limiting element is configured to receive the gate drive signal as a supply input, and limit the gate drive signal at an output of the voltage-limiting element such that the JFET gate potential is limited to the controlled overdrive value.

8. The JFET cascode circuit of claim 7, wherein the voltage-limiting element is a transistor, and
wherein the voltage-limiting circuit further comprises:
a voltage reference element coupled between a control terminal of the voltage-limiting element and a reference node of the JFET cascode circuit, wherein the voltage reference element is configured to be biased by the gate drive signal such that a signal provided by the voltage reference element depends on a state of the gate drive signal,
wherein the gate driver is configured to drive the gate drive signal between a high level and a low level, and
wherein the voltage reference element is configured to, based on the gate drive signal being at the high level, conduct current in a reverse-conduction mode and set a voltage at the control terminal of the voltage-limiting element to a reverse-bias reference voltage.

9. The JFET cascode circuit of claim 8, wherein the voltage reference element is a Zener diode having a first cathode coupled to the reference node of the JFET cascode circuit, and a first anode coupled to the control terminal of the voltage-limiting element, and wherein a bias resistor is coupled to the gate drive terminal and the first anode of the Zener diode.

10. The JFET cascode circuit of claim 8, wherein the voltage-limiting circuit further comprises:
a diode having a second cathode coupled to the gate drive terminal, and a second anode coupled to the output of the voltage-limiting element and to the JFET gate terminal,
wherein the diode is configured to, based on the gate drive signal being at the low level, discharge the JFET gate terminal to the low level.

11. The JFET cascode circuit of claim 1, wherein the unipolar supply scheme includes a supply potential, sufficient for satisfying the controlled overdrive value, and a reference potential, and
wherein the voltage-limiting element is configured to receive the supply potential as a supply input, and limit the supply potential at an output of the voltage-limiting element such that the JFET gate potential is limited to the controlled overdrive value.

12. The JFET cascode circuit of claim 11, wherein the voltage-limiting element is a transistor, and
wherein the voltage-limiting circuit further comprises:
a voltage reference element coupled between a control terminal of the voltage-limiting element and a reference node of the JFET cascode circuit, wherein the voltage reference element is configured to be biased by the gate drive signal such that a signal provided by the voltage reference element depends on a state of the gate drive signal,
wherein the gate driver is configured to drive the gate drive signal between a high level and a low level, and
wherein the voltage reference element is configured to, based on the gate drive signal being at the high level, conduct current in a reverse-conduction mode and set a voltage at the control terminal of the voltage-limiting element to a reverse-bias reference voltage.

13. The JFET cascode circuit of claim 1, wherein the voltage-limiting element is configured to, during an off-condition of the JFET, set the JFET gate potential to a low-voltage level of the unipolar supply scheme.

14. A junction field effect transistor (JFET) cascode control circuit configured to control a JFET cascode circuit that comprises a voltage-controlled transistor that is coupled to a JFET in a cascode configuration, the JFET cascode control circuit comprising:
a gate driver configured to be supplied according to a unipolar supply scheme, the gate driver configured to receive a control signal and to, based on the control signal, output a gate drive signal from a gate drive terminal configured to be coupled to a gate terminal of the voltage-controlled transistor, and
a voltage-limiting circuit coupled to the gate drive terminal and comprising an overdrive terminal configured to be coupled to a JFET gate terminal of the JFET, the voltage-limiting circuit comprising a voltage-limiting element configured to output a regulated signal at the overdrive terminal based on the gate drive signal such that, during a steady-state on-condition of the JFET, a maximum of a JFET gate potential is limited to a controlled overdrive value,
wherein the voltage-limiting element is an active device.

15. The junction field effect transistor (JFET) cascode control circuit of claim 14, wherein the unipolar supply scheme includes a supply potential, sufficient for satisfying the controlled overdrive value, and a reference potential,
wherein, when the control signal indicates a turn on of the JFET cascode circuit:
the gate driver is configured to set the gate drive signal to the supply potential to turn on the voltage-controlled transistor and the voltage-limiting element is configured output the regulated signal in accordance with the controlled overdrive value, and
wherein, when the control signal indicates a turn off of the JFET cascode circuit:
the gate driver is configured to set the gate drive signal to the reference potential to turn off the voltage-controlled transistor and the voltage-limiting element is configured to set the overdrive terminal to the reference potential.

16. The junction field effect transistor (JFET) cascode control circuit of claim 14, wherein the voltage-limiting element is configured to receive the gate drive signal as a supply input, and limit the gate drive signal at an output of the voltage-limiting element such that the regulated signal at the overdrive terminal is limited to the controlled overdrive value.

17. The JFET cascode control circuit of claim 16, wherein the voltage-limiting element is a transistor, and
wherein the voltage-limiting circuit further comprises:
a voltage reference element coupled between a control terminal of the voltage-limiting element and a reference node, wherein the voltage reference element is configured to be biased by the gate drive signal such that a signal provided by the voltage reference element depends on a state of the gate drive signal,
wherein the gate driver is configured to drive the gate drive signal between a high level and a low level, and
wherein the voltage reference element is configured to, based on the gate drive signal being at the high level, conduct current in a reverse-conduction mode and set a voltage at the control terminal of the voltage-limiting element to a reverse-bias reference voltage.

18. The JFET cascode control circuit of claim 17, wherein the voltage-limiting circuit further comprises:
a diode having a second cathode coupled to the gate drive terminal, and a second anode coupled to the output of the voltage-limiting element and to the overdrive terminal,
wherein the diode is configured to, based on the gate drive signal being at the low level, sink a current from the overdrive terminal to discharge the JFET gate terminal to the low level.

19. The JFET cascode control circuit of claim 14, wherein the unipolar supply scheme includes a supply potential, sufficient for satisfying the controlled overdrive value, and a reference potential, and
wherein the voltage-limiting element is configured to receive the supply potential as a supply input, and limit the supply potential at an output of the voltage-limiting element such that the regulated signal at the overdrive terminal is limited to the controlled overdrive value.

20. The JFET cascode control circuit of claim 19, wherein the voltage-limiting element is a transistor, and
wherein the voltage-limiting circuit further comprises:
a voltage reference element coupled between a control terminal of the voltage-limiting element and a reference node, wherein the voltage reference element is configured to be biased by the gate drive signal such that a signal provided by the voltage reference element depends on a state of the gate drive signal,
wherein the gate driver is configured to drive the gate drive signal between a high level and a low level, and
wherein the voltage reference element is configured to, based on the gate drive signal being at the high level, conduct current in a reverse-conduction mode and set a voltage at the control terminal of the voltage-limiting element to a reverse-bias reference voltage.
